(19) United States
(12) Patent Application Publication
(10) Pub. No.: US 2025/0098433 A1
(43) Pub. Date: Mar. 20, 2025

(54) DISPLAY DEVICE INCLUDING REFLECTION LAYER AND METHOD OF MANUFACTURING THE SAME

(71) Applicant: SAMSUNG DISPLAY CO., LTD., Yongin-si (KR)

(72) Inventors: Israel Esteban Lazo Martinez, Yongin-si (KR); Sukhoon Kang, Yongin-si (KR); Hyungguen Yoon, Yongin-si (KR); Sunghwan Hong, Yongin-si (KR)

(21) Appl. No.: 18/797,081

(22) Filed: Aug. 7, 2024

(30) Foreign Application Priority Data
Sep. 14, 2023 (KR) 10-2023-0122663

(51) Int. Cl. H10K 59/122; H10K 59/12; H10K 59/80

(52) U.S. Cl. CPC H10K 59/122; H10K 59/1201; H10K 59/878

(57) ABSTRACT

A method of manufacturing a display device includes disposing a material precursor of a bank layer on a substrate, irradiating first ultraviolet rays onto at least a portion of the material precursor to form a first reflection portion, and removing at least a portion of the material precursor to form the bank layer.

### CROSS-REFERENCE TO RELATED APPLICATION

This application is based on and claims priority under 35 U.S.C. § 119 to Korean Patent Application No. 10-2023-0122663, filed on Sep. 14, 2023, in the Korean Intellectual Property Office, the disclosure of which is incorporated by reference herein in its entirety.

### BACKGROUND

### 1. Technical Field

One or more embodiments relate to a display device including a reflection layer, and a method of manufacturing the same.

### 2. Description of Related Art

Display devices may visually display data. A display device may be used as a display unit of a small-sized product, such as a mobile phone, or a large-sized product, such as a television.

The display device may be configured using a liquid crystal display device using backlight a light-emitting display device including a display element capable of emitting light. The display element may include an emission layer.

### SUMMARY

One or more embodiments include a display device including a reflection layer and a method of manufacturing the same.

Aspects of the present disclosure will be set forth in part in the description which follows and, in part, will be apparent from the description, or may be learned by practice of embodiments thereof.

According to one or more embodiments, a method of manufacturing a display device includes disposing a material precursor of a bank layer on a substrate, irradiating first ultraviolet rays onto at least a portion of the material precursor to form a first reflection portion, and removing at least a portion of the material precursor to form the bank layer.

The method may further include disposing a photomask onto the material precursor before the irradiating the first ultraviolet rays onto the portion of the material precursor, wherein the portion of the material precursor removed includes a portion of the material not irradiated by the first ultraviolet rays.

The material precursor may include silver ions (Ag+) and the irradiating of the first ultraviolet rays onto the portion of the material precursor may include reducing the Ag+ to silver (Ag).

The material precursor may include an acryl-based monomer or an epoxy-based monomer, wherein the irradiating of the first ultraviolet rays onto the portion of the material precursor may include synthesizing the acryl-based monomer or the epoxy-based monomer into a polymer.

The material for forming a bank layer may include at least one of a photoinitiator or a photosensitizer.

The material precursor may include silver nitrate (AgNO₃) and the irradiating of the first ultraviolet rays onto the portion of the material precursor comprises reducing silver ions (Ag+) of a AgNO₃ to silver (Ag).

A photomask may be aligned to the material precursor using infrared rays, and a transmittance of the material precursor to the infrared rays may be about 14% or higher.

In the irradiating of the first ultraviolet rays onto the portion of the material precursor, an intensity of the first ultraviolet rays may be in a range from about 10 mJ to about 1,500 mJ.

The irradiating of the first ultraviolet rays onto the portion of the material precursor may include generating free radicals from a photosensitive material to provide free electrons to the Ag+ of the material precursor.

In the irradiating of the first ultraviolet rays onto the portion of the material precursor, Ag atoms may aggregate to form Ag colloidal nanoparticles.

A method may further include irradiating second ultraviolet rays onto the bank layer after the forming of the bank layer to form a second reflection portion at a side surface of the bank layer.

A method may further include curing the bank layer by applying heat thereto after the irradiating of the second ultraviolet rays onto the bank layer.

A reflection layer may be formed of the first reflection portion disposed at an upper surface of the bank layer and the second reflection portion disposed at the side surface of the bank layer and the reflection layer may include Ag.

A transmittance of the reflection layer of the bank layer to visible light may be about 70% or higher.

According to an embodiment, a method of manufacturing a display device may include disposing a material precursor of a bank layer on an encapsulation layer, irradiating first ultraviolet rays onto at least a portion of the material precursor to form a first reflection portion at an upper surface of the material precursor, removing, after forming the first reflection portion, at least a portion of the material precursor disposed above a pixel electrode to form a bank layer, and irradiating second ultraviolet rays onto the bank layer to form a second reflection portion at a side surface of the bank layer.

A method may further include curing the bank layer by applying heat after the irradiating of the second ultraviolet rays onto the bank layer.

The material precursor may include silver ions (Ag+), and an acryl-based monomer or an epoxy-based monomer, wherein the irradiating of the first ultraviolet rays onto the portion of the material precursor may include simultaneously synthesizing the acryl-based monomer or the epoxy-based monomer into a polymer and reducing the silver ions (Ag+) to silver (Ag).

According to an embodiment, a display device may include a substrate, a bank layer disposed above the substrate and comprising a reflection layer formed of silver (Ag) at an upper surface and a side surface of the bank layer, and a central portion comprising Ag ions (Ag+), and a light-transmissive layer, a first-color quantum dot layer, and a second-color quantum dot layer disposed in openings of the bank layer.

The bank layer may include an epoxy-based polymer or an acryl-based polymer.

A transmittance of the reflection layer of the bank layer to visible light may be about 70% or higher.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view of a display device according to an embodiment;

FIG. 2 is a schematic cross-sectional view of respective pixels of a display device, according to an embodiment;

FIG. 3 shows each optical unit of a color conversion-penetration layer of FIG. 2;

FIG. 4 is an equivalent circuit diagram of a light-emitting diode and a pixel circuit electrically connected to the light-emitting diode, which are included in a display device, according to an embodiment;

FIG. 5 is a schematic cross-sectional view of the display device, taken along a line I-I′ of FIG. 1;

FIG. 6 is an enlarged cross-sectional view showing a bank layer, according to an embodiment;

FIG. 7, FIG. 8, FIG. 9, FIG. 10, FIG. 11, and FIG. 12 are schematic cross-sectional views of a method of manufacturing a bank layer; and

FIG. 13 is a flow diagram of a method of manufacturing a bank layer.

### DETAILED DESCRIPTION

Reference will now be made in detail to embodiments, examples of which are illustrated in the accompanying drawings. In the drawings, like reference numerals refer to like elements throughout and repeated descriptions thereof may be omitted. Embodiments may have different forms and should not be construed as being limited to the descriptions set forth herein. Accordingly, embodiments are described by referring to the figures to explain aspects of the present description.

As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Hereinafter, one or more embodiments of the disclosure will be described in detail with reference to the accompanying drawings. However, the disclosure may, however, be embodied in many different forms and should not be construed as being limited to embodiments set forth herein. Embodiments are provided to sufficiently convey the scope of this inventive concept to those skilled in the art.

It will be understood that although the terms “first,” “second,” etc. may be used herein to describe various elements, these elements should not be limited by these terms, and these terms may be used to merely distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, sizes and thicknesses of elements in the drawings may be arbitrarily illustrated, for example, for convenience of explanation, and embodiments are not limited thereto.

Embodiments may be implemented differently from aspects described herein, and a specific process order may be performed differently from a described order. For example, two consecutively described processes may be performed substantially at the same time or performed in an order different than the described order.

It will be understood that when a layer, region, or component is referred to as being connected to another layer, region, or component, it can be directly and/or indirectly connected to the other layer, region, or component. That is, for example, intervening layers, regions, or components may be present. For example, when a layer, region, or component is referred to as being electrically connected to another layer, region, or component, it can be directly or indirectly electrically connected to the other layer, region, or component.

In the following examples, an x-axis, a y-axis, and a z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

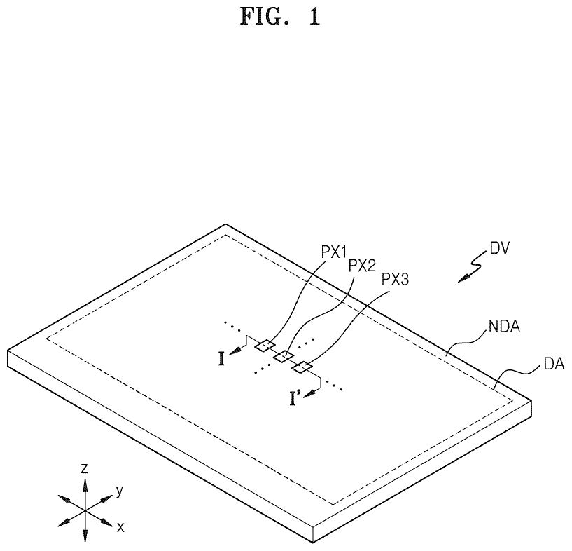

FIG. 1 is a schematic perspective view of a display device according to an embodiment.

Referring to FIG. 1, a display device DV may include a display area DA and a non-display area NDA disposed on a periphery of the display area DA. The display device DV may provide images through an array of pixels that are two-dimensionally arranged in an x-y plane in the display area DA. The pixels may include a first pixel PX1, a second pixel PX2, and a third pixel PX3. The pixels may display different colors. For example, the first pixel PX1 may be a blue pixel, the second pixel PX2 may be a green pixel, and the third pixel PX3 may be a red pixel.

The first pixel PX1, the second pixel PX2, and the third pixel PX3 may be areas where blue light, green light, and red light may be emitted, respectively, and the display device DV may provide images by using light emitted from the pixels.

The non-display area NDA may be an area where no images are displayed and may entirely surround the display area DA. Various circuits or devices may be provided in the non-display area NDA. For example, drivers or main voltage lines configured to provide electrical signals or power to pixel circuits may be arranged in the non-display area NDA. Further, a pad that may be electrically connected to an electronic component or a printed circuit board may be disposed in the non-display area NDA.

The display area DA may have a polygonal shape including a rectangular shape, as shown in FIG. 1. For example, the display area DA may have a rectangular shape in which a horizontal length may be greater than a vertical length, or the horizontal length may be less than the vertical length, or may have a square shape. Alternatively, the display area DA may have others shapes such as an oval shape or a circular shape.

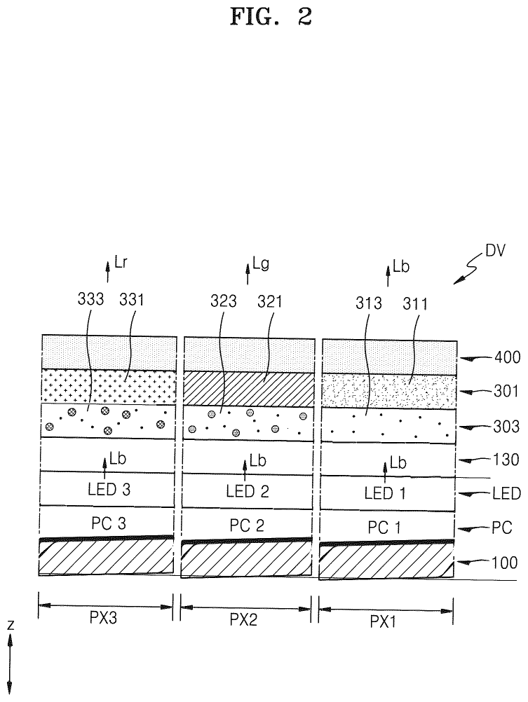

FIG. 2 is a schematic cross-sectional view of respective pixels of the display device, according to an embodiment.

Referring to FIG. 2, the display device DV may include a circuit layer PC on a lower substrate 100. The circuit layer PC may include a first pixel circuit PC1, a second pixel circuit PC2, and a third pixel circuit PC3. The first pixel circuit PC1 to the third pixel circuit PC3 may be electrically connected to a first light-emitting diode LED1, a second light-emitting diode LED2, and a third light-emitting diode LED3 of a light-emitting diode layer LED, respectively. The first light-emitting diode LED1 to the third light-emitting diode LED3 may be disposed on the first pixel circuit PC1 to the third pixel circuit PC3, respectively.

The first light-emitting diode LED1 to the third light-emitting diode LED3 may include organic light-emitting diodes including organic materials. Alternatively, the first light-emitting diode LED1 to the third light-emitting diode LED3 may include inorganic light-emitting diodes including inorganic materials. The inorganic light-emitting diode may include a PN junction diode including materials based on an inorganic semiconductor. When a voltage is applied to a PN junction diode in a forward direction, electrons and holes may be injected, and energy generated from a recombination of the electrons and holes may be converted into light energy, and light of a certain color may be emitted. The inorganic light-emitting diode described herein may have a width of several to several hundred micrometers or several to several hundred nanometers. Alternatively, the light-emitting diode LED may be a light-emitting diode including quantum dots. As described herein, an emission layer of the light-emitting diode LED may include organic materials, inorganic materials, quantum dots, both organic materials and quantum dots, or both inorganic materials and quantum dots.

The quantum dots may be photo-active, capable of absorbing and then emitting light. A color of light that a quantum dot emits may depend on a size of the quantum dot. For example, a quantum dot with a core diameter of between about 6 and 7 nanometers may emit red.

An encapsulation layer 130 may be disposed on the first light-emitting diode LED1 to third light-emitting diode LED3. A color conversion-penetration layer 303 may be disposed on the encapsulation layer 130. The first light-emitting diode LED1 to the third light-emitting diode LED3 may emit light having a same color. For example, light (e.g., blue light Lb) emitted from the first light-emitting diode LED1 to third light-emitting diode LED3 may pass through the encapsulation layer 130 and the color conversion-penetration layer 303.

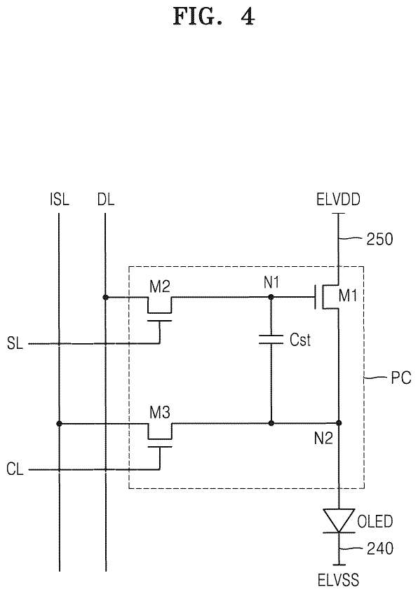

The color conversion-penetration layer 303 may include optical units that transmit a color of the light (e.g., the blue light Lb) emitted from the light-emitting diode layer LED with or without converting the color of the emitted light. For example, the color conversion-penetration layer 303 may include quantum dot layers that convert the light (e.g., the blue light Lb) emitted from the light-emitting diode layer LED into different colors of light, and a light-transmissive layer 313 that passes the light (e.g., the blue light Lb) emitted from the light-emitting diode layer LED without changing its color. The color conversion-penetration layer 303 may include a third-color quantum dot layer 333 corresponding to a red pixel, a second-color quantum dot layer 323 corresponding to a green pixel, and the light-transmissive layer 313 corresponding to a blue pixel. The third-color quantum dot layer 333, the second-color quantum dot layer 323, and the light-transmissive layer 313 of color conversion-penetration layer 303 may be disposed in openings of the bank layer 500 (see FIG. 4).

In an embodiment, the third-color quantum dot layer 333 may convert the blue light Lb into red light Lr, and the second-color quantum dot layer 323 may convert the blue light Lb into green light Lg. The light-transmissive layer 313 may pass the blue light Lb without changing its color.

A color filter layer 301 may be disposed above the color conversion-penetration layer 303. The color filter layer 301 may include a first color filter layer 311, a second color filter layer 321, and a third color filter layer 331 of different colors. For example, the first-color color filter layer 311 may be a blue color filter, the second-color color filter layer 321 may be a green color filter, and the third-color color filter layer 331 may be a red color filter.

The light, the color of which may be converted and transmitted by the color conversion-penetration layer 303, may pass through the first-color color filter layer 311 to the third-color color filter layer 331. The light converted and transmitted by the color conversion-penetration layer 303 and passed through the first-color color filter layer 311 to the third-color color filter layer 331 may have improved color purity. Also, the color filter layer 301 may prevent or reduce external light (e.g., light that is incident towards the display device DV from the outside thereof) from being reflected and viewed by users.

An upper substrate 400 may be disposed above the color filter layer 301. The upper substrate 400 may include glass or a light-transmissive organic material. For example, the upper substrate 400 may include a light-transmissive organic material, such as acryl-based resin.

In an embodiment, the upper substrate 400 may be a type of substrate. The color filter layer 301 and the color conversion-penetration layer 303 may be formed on the upper substrate 400. The upper substrate 400, the color filter layer 301, and the color conversion-penetration layer 303 may be disposed on the encapsulation layer 130, with the color conversion-penetration layer 303 facing the encapsulation layer 130.

Alternatively, the color conversion-penetration layer 303 and the color filter layer 301 may be sequentially formed on the encapsulation layer 130, and the upper substrate 400 may be formed on the color filter layer 301 through direct spreading and curing of the upper substrate 400. Although not shown, other optical films, such as an anti-reflection (AR) film, may be disposed on the upper substrate 400.

The display device DV may be integrated into various devices, such as, a television, a billboard, a cinema screen, a monitor, a tablet personal computer (PC), a laptop, etc.

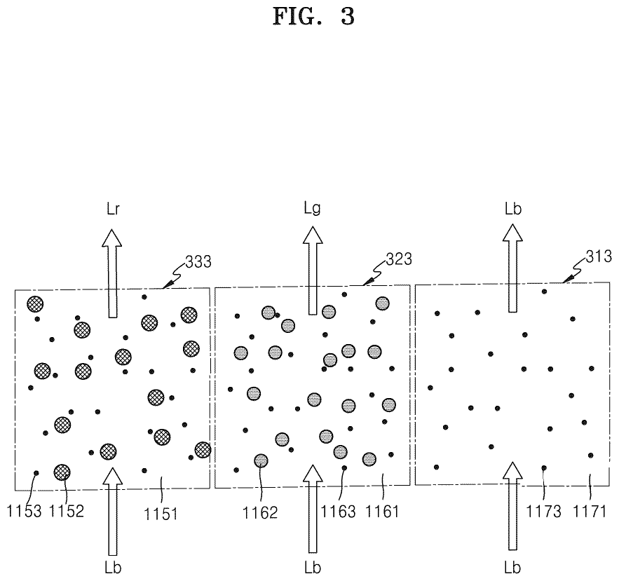

FIG. 3 illustrates optical units of the color conversion-penetration layer of FIG. 2.

Referring to FIG. 3, the third-color quantum dot layer 333 may convert incident blue light Lb into red light Lr. As shown in FIG. 3, the third-color quantum dot layer 333 may include a first photosensitive polymer 1151, third-color quantum dots 1152, first scattering particles 1153. The third-color quantum dots 1152 and first scattering particles 1153 may be distributed in the first photosensitive polymer 1151.

The third-color quantum dots 1152 may be excited by the blue light Lb and isotropically emit the red light Lr having a greater wavelength than the blue light Lb. The first photosensitive polymer 1151 may include an organic material that is light-transmissive.

The first scattering particles 1153 may increase the color conversion efficiency by scattering the blue light Lb. For example, the first scattering particles 1153 may scatter a portion of the blue light Lb that has not yet been absorbed into the third-color quantum dots 1152, which may increase a probability that the blue light Lb interacts with the third-color quantum dots 1152. The first scattering particles 1153 may be, for example, titanium oxide (TiO₂), or metal particles. The third-color quantum dots 1152 may be selected from among II-VI group compounds, III-V group compounds, IV-VI group compounds, IV group elements, IV group compounds, or a combination thereof.

The second-color quantum dot layer 323 may convert incident blue light Lb into green light Lg. As shown in FIG. 3, the second-color quantum dot layer 323 may include a second photosensitive polymer 1161, second-color quantum dots 1162, and second scattering particles 1163. The second-color quantum dots 1162 and the second scattering particles 1163 may be distributed in the second photosensitive polymer 1161.

The second-color quantum dots 1162 may be excited by the blue light Lb and isotropically emit green light Lg having a greater wavelength than the blue light Lb. The second photosensitive polymer 1161 may include an organic material that is light-transmissive.

The second scattering particles 1163 may increase the color conversion efficiency by scattering the blue light Lb. For example, the second scattering particles 1163 may scatter a portion of the blue light Lb that has not yet been absorbed into the second-color quantum dots 1162, which may increase a probability that the blue light Lb interacts with the second-color quantum dots 1162. The second scattering particles 1163 may be, for example, TiO₂, or metal particles. The second-color quantum dots 1162 may be selected from among II-VI group compounds, III-V group compounds, IV-VI group compounds, IV group elements, IV group compounds, or a combination thereof.

In an embodiment, the third-color quantum dots 1152 and the second-color quantum dots 1162 may include the same materials. In an embodiment, sizes of the third-color quantum dots 1152 may be greater than sizes of the second-color quantum dots 1162.

The transmissive layer 313 may transmit the blue light Lb without converting the blue light Lb that is incident onto the light-transmissive layer 313. As shown in FIG. 3, the light-transmissive layer 313 may include a third photosensitive polymer 1171. The third scattering particles 1173 may be distributed in the third photosensitive polymer 1171. The third photosensitive polymer 1171 may include an organic material, for example, silicon resin or epoxy resin, which may be light-transmissive and may include the same material as the first photosensitive polymer 1151 and the second photosensitive polymer 1161. The third scattering particles 1173 may scatter and emit the blue light Lb and include the same material as the first scattering particles 1153 and the second scattering particles 1163.

FIG. 4 is an equivalent circuit diagram of a light-emitting diode and a pixel circuit electrically connected to the light-emitting diode, which may be included in a display device, according to an embodiment.

Referring to FIG. 4, a first electrode (e.g., an anode) of a light-emitting diode, e.g., the light-emitting diode LED, may be connected to a pixel circuit PC, and a second electrode (e.g., a cathode) of the light-emitting diode LED may be connected to a common voltage line VSL configured to provide a common power voltage ELVSS. The light-emitting diode LED may emit light at a brightness corresponding to an electric current provided from the pixel circuit PC.

The light-emitting diode LED of FIG. 4 may correspond to each of the first light-emitting diodes LED1 to third light-emitting diodes LED3 described herein with reference to FIG. 2, and the pixel circuit PC of FIG. 4 may correspond to each of the first pixel circuit PC1 to the third pixel circuit PC3 described herein with reference to FIG. 2.

The pixel circuit PC may control the amount of current flowing from a driving power voltage ELVDD to the common power voltage ELVSS via the light-emitting diode LED, in response to a data signal. The pixel circuit PC may include a driving transistor M1, a switching transistor M2, a sensing transistor M3, and a storage capacitor Cst.

The driving transistor M1, the switching transistor M2, and the sensing transistor M3 may each be an oxide semiconductor thin-film transistor including a semiconductor layer including an oxide semiconductor, or a silicon semiconductor thin-film transistor including a semiconductor layer including polysilicon. The driving transistor M1, the switching transistor M2, and the sensing transistor M3 may each include a source electrode (or a source area) and a drain electrode (or a drain area).

The source electrode (or the source area) of the driving transistor M1 may be connected to a driving voltage line VDL (not illustrated) configured to provide the driving power voltage ELVDD, and the drain electrode (or the drain area) of the driving transistor M1 may be connected to the first electrode (e.g., the anode) of the light-emitting diode LED. A gate electrode of the driving transistor M1 may be connected to a first node N1. The driving transistor M1 may control the amount of current flowing in the light-emitting diode LED from the driving power voltage ELVDD according to a voltage of the first node N1, but the locations of the source electrode (or the source area) and the drain electrode (or the drain area) of the driving transistor M1 may change.

The source electrode (or the source area) of the switching transistor M2 may be connected to the data line DL, and the drain electrode (or the drain area) of the switching transistor M2 may be connected to the first node N1. A gate electrode of the switching transistor M2 may be connected to a scan line SL. The switching transistor M2 may be turned on when a scan signal is provided to the scan line SL and may electrically connect the data line DL to the first node N1. However, the locations of the source electrode (or the source area) and the drain electrode (or the drain area) of the switching transistor M2 may change.

The sensing transistor M3 may be an initialization transistor and/or a sensing transistor. The drain electrode (or the drain area) of the sensing transistor M3 may be connected to a second node N2, and the source electrode (or the source area) of the sensing transistor M3 may be connected to a sensing line SEL. A gate electrode of the sensing transistor M3 may be connected to a control line CL. However, the locations of the source electrode (or the source area) and the drain electrode (or the drain area) of the sensing transistor M3 may change.

The storage capacitor Cst may be connected between the first node N1 and the second node N2. For example, a first capacitor electrode of the storage capacitor Cst may be connected to the gate electrode of the driving transistor M1, and a second capacitor electrode of the storage capacitor Cst may be connected to the first electrode (e.g., the anode) of the light-emitting diode LED.

In the light-emitting diode LED of FIG. 4, the driving transistor M1, the switching transistor M2, and the sensing transistor M3 may each be an NMOS transistor, but embodiments are not limited thereto. For example, at least one of the driving transistor M1, the switching transistor M2, and the sensing transistor M3 may be a PMOS transistor.

The light-emitting diode LED of FIG. 4 includes three transistors, but embodiments are not limited thereto. For example, the pixel circuit PC may include four or more transistors.

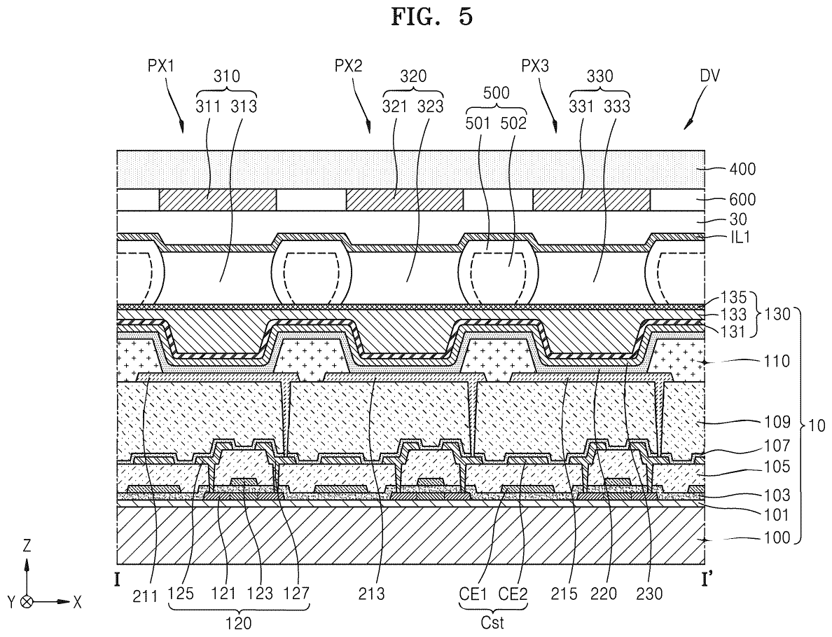

FIG. 5 is a schematic cross-sectional view of the display device DV, taken along a line I-I′ of FIG. 1.

Referring to FIG. 5, the display device DV according to an embodiment may include a display unit 10, quantum dot layers 323 and 333, a light-transmissive layer 313, color filter layers 311 to 313, and an adhesive layer 30.

The display unit 10 includes a lower substrate 100. The lower substrate 100 may include a glass material, a metal material, a ceramic material, or a flexible or bendable material. When the lower substrate 100 is flexible or bendable, the lower substrate 100 may include, for example, polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The lower substrate 100 may have a single-layer structure or a multilayered structure including the above materials, and when the lower substrate 100 has a multilayered structure, various modifications may be made to the lower substrate 100; for example, the lower substrate 100 has a multilayered structure that includes two layers including polymer resin and a barrier layer disposed between the two layers and including an inorganic material (silicon oxide, silicon nitride, silicon oxynitride, or the like).

A buffer layer 101 may be disposed above the lower substrate 100. The buffer layer 101 may include an inorganic material, such as silicon oxide, silicon nitride, and/or silicon oxynitride and may be a layer or layers. The buffer layer 101 may improve the flatness of an upper surface of the lower substrate 100 or prevent or reduce the penetration of impurities or moisture from an outer side of the lower substrate 100 into a semiconductor layer 121 of a thin-film transistor 120.

A pixel circuit may be disposed above the buffer layer 101, and above the pixel circuit, a display element layer electrically connected to the pixel circuit and including a first display element to a third display element may be disposed. Also, the pixel circuit may include the thin-film transistor 120 and a capacitor Cst. The electrical connection of the first display element to the third display element to the pixel circuit may be understood that pixel electrodes 211, 213, and 215 of the first display element to the third display element are electrically connected to the thin-film transistor 120.

The thin-film transistor 120 may include a semiconductor layer 121 including amorphous silicon, polycrystalline silicon, or an organic semiconductor material, a gate electrode 123, a source electrode 125, and a drain electrode 127.

The semiconductor layer 121 may be disposed above the buffer layer 101 and include amorphous silicon or polysilicon. As a detailed example, the semiconductor layer 121 may include oxide of at least one material selected from indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), or zinc (Zn). The semiconductor layer 121 may include a Zn-oxide-based material and include Zn oxide, In—Zn oxide, Ga—In—Zn oxide, or the like. Also, the semiconductor layer 121 may be an In—Ga—Zn—O (IGZO) semiconductor, an In—Sn—Zn—O (ITZO) semiconductor, or an In—Ga—Sn—Zn—O (IGTZO) semiconductor in which metal such as In, Ga, or Sn is included in ZnO. The semiconductor layer 121 may include a channel area and a source area, and a drain area arranged on sides of the channel area.

The gate electrode 123 may be disposed above the semiconductor layer 121 to overlap at least partially the same. The gate electrode 123 may include various conductive materials including Mo, Al, Cu, or Ti, and have various layer structures. For example, the gate electrode 123 may include a Mo layer and an Al layer, or have a multilayered structure including Mo/Al/Mo.

The source electrode 125 and the drain electrode 127 may each include various conductive materials including Mo, Al, Cu, or Ti, and have various layer structures. For example, the source electrode 125 and the drain electrode 127 may include a Ti layer and an Al layer, or have a multilayered structure including Ti/Al/Ti. The source electrode 125 may contact a source area of the semiconductor layer 121 through a first contact hole. The drain electrode 127 may contact a drain area of the semiconductor layer 121 through a second contact hole.

To insulate the semiconductor layer 121 from the gate electrode 123, a gate insulating layer 103, which may include an inorganic material such as silicon oxide, silicon nitride, and/or silicon oxynitride, may be disposed between the semiconductor layer 121 and the gate electrode 123. In addition, a first interlayer insulating layer 105 may be disposed above the gate electrode 123. The first interlayer insulating layer 105 may have a certain permittivity, and the first interlayer insulating layer 105 may be an insulating layer that includes an inorganic material, such as silicon oxide, silicon nitride, and/or silicon oxynitride. The source electrode 125 and the drain electrode 127 may be disposed above the first interlayer insulating layer 105. An insulating layer (or film) including the inorganic material may be formed through chemical vapor deposition (CVD) or atomic layer deposition (ALD).

The capacitor Cst may include a first electrode CE1 and a second electrode CE2. The second electrode CE2 may be disposed over the first electrode CE1. The first electrode CE1 and the second electrode CE2 may at least partially overlap each other. The first interlayer insulating layer 105 may be disposed between the first electrode CE1 and the second electrode CE2. The first electrode CE1 and the second electrode CE2, separated by the first interlayer insulating layer 105, may be configured to store an electric charge. In this case, the first interlayer insulating layer 105 may function as a dielectric layer of the capacitor Cst.

The first electrode CE1 may be disposed at a same level as the gate electrode 123. The first electrode CE1 may include the same material as the gate electrode 123. For example, the first electrode CE1 may include various conductive materials including Mo, Al, Cu, or Ti, and have various layer structures (e.g., a multilayered structure of Mo/Al/Mo). The second electrode CE2 may be disposed at a same level as the source electrode 125 and the drain electrode 127. The second electrode CE2 may include the same material as the source electrode 125 and the drain electrode 127. For example, the second electrode CE2 may include various conductive materials including Mo, Al, Cu, or Ti, and have various layer structures (e.g., a multilayered structure of Ti/Al/Ti).

A planarization layer 109 may be disposed above the thin-film transistor 120 and the capacitor Cst. When organic light-emitting diodes are disposed above the thin-film transistor 120 as an example of the first to third display elements, the planarization layer 109 may substantially flatten an upper portion of a protective layer covering the thin-film transistor 120. The planarization layer 109 may include a general-purpose polymer, such as benzocyclobutene (BCB), polyimide, hexamethyldisiloxane (HMDSO), polymethylmethacrylate (PMMA), or polystyrene (PS), a polymer derivative having a phenol-based group, an acryl-based polymer, an imide-based polymer, an aryl-ether-based polymer, an amide-based polymer, a fluorine-based polymer, a p-xylene-based polymer, or a vinyl alcohol-based polymer, or any combination thereof.

The first display element to the third display element may be disposed above the planarization layer 109. The first display element to the third display element may be organic light-emitting diodes that include the pixel electrodes 211, 213, and 215, the opposite electrode 230, and an intermediate layer 220 disposed between the pixel electrodes 211, 213, and 215 and the opposite electrode 230.

In an embodiment, the first display element to the third display element may include the first pixel electrode 211, the second pixel electrode 213, and the third pixel electrode 215, the opposite electrode 230 corresponding to the first pixel electrode 211, the second pixel electrode 213, and the third pixel electrode 215, and the intermediate layer 220 disposed between the opposite electrode 230 and the first pixel electrode 211 to the third pixel electrode 215. Also, the intermediate layer 220 may include a first-color emission layer configured to emit light in a wavelength included in a first wavelength band. For example, the first wavelength band may be between about 450 nm and 495 nm, and the first color may be blue. However, embodiments are not limited thereto.

The first pixel electrode 211 to the third pixel electrode 215 of the first display element to the third display element may contact any one of the source electrode 125 and the drain electrode 127 through an opening (a contact hole) formed in the planarization layer 109, and may be electrically connected to the thin-film transistor 120. The first pixel electrode 211 to the third pixel electrode 215 may each be a transparent (or translucent) electrode or a reflection electrode. In one or more embodiments, the first pixel electrode 211 to the third pixel electrode 215 may each include a reflection layer including silver (Ag), magnesium (Mg), Al, platinum (Pt), palladium (Pd), gold (Au), nickel (Ni), neodymium (Nd), iridium (Ir), or chromium (Cr), or a compound thereof, and a transparent or translucent electrode layer formed on the reflection layer. The transparent or translucent electrode layer may include at least one material selected from indium tin oxide (ITO), indium zinc oxide (IZO), zinc oxide (ZnO), indium oxide (In₂O₃), indium gallium oxide (IGO), or aluminum zinc oxide (AZO). Also, the first pixel electrode 211 to the third pixel electrode 215 may have a stack structure of ITO/Ag/ITO.

A pixel-defining layer 110 may be disposed above the planarization layer 109. The pixel-defining layer 110 may define a pixel (or an emission area) by having an opening corresponding to each sub-pixel. In this case, the opening is formed to expose at least a portion of central portions of the first pixel electrode 211 to the third pixel electrode 215. For example, the pixel-defining layer 110 may be located between the first display element and the second display element, the second display element and the third display element, and the first display element and the third display element.

The pixel-defining layer 110 may prevent arcs, etc. from being generated at edges of the first pixel electrode 211 to the third pixel electrode 215 by increasing distances between the edges of the first pixel electrode 211 to the third pixel electrode 215 and the opposite electrode 230 above the first pixel electrode 211 to the third pixel electrode 215. The pixel-defining layer 110 may include one or more organic insulating materials selected from polyamide, polyimide, acryl resin, BCB, or phenol resin, and may be formed through a spin coating method or the like.

The intermediate layer 220 of the first display element to the third display element may include a low-molecular-weight material or a high-molecular-weight material. When the intermediate layer 220 includes a low-molecular-weight material, the intermediate layer 220 may have a structure in which a hole injection layer (HIL), a hole transport layer (HTL), an emission layer (EML), an electron transport layer (ETL), and an electron injection layer (EIL) are stacked in a single or complex structure and may be formed through vacuum deposition. When the intermediate layer 220 includes a high-molecular-weight material, the intermediate layer 220 may have a structure including an HTL and an EML. In this case, the HTL may include PEDOT, and the emission layer may include a high-molecular-weight material, such as poly-phenylenevinylene (PPV)-based material or a polyfluorene-based material. The intermediate layer 220 may be formed according to a screen printing method, an inkjet printing method, a deposition method, or a laser induced thermal imaging (LITI) method, or the like. The intermediate layer 220 is not limited thereto and may have various structures.

As described herein, the intermediate layer 220 may include a layer that is integrally formed over the first pixel electrode 211 of the first display element to the third pixel electrode 215 of the third display element. The intermediate layer 220 may include a layer that is patterned to correspond to each of the first pixel electrode 211 to the third pixel electrode 215. In an embodiment, the intermediate layer 220 may include a first-color emission layer. The first-color emission layer may be integrally formed over the first pixel electrode 211 to the third pixel electrode 215 or may be patterned to correspond to each of the first pixel electrode 211 to the third pixel electrode 215. The first-color emission layer may emit light in a wavelength included in the first wavelength band and emit, for example, light in a wavelength ranging from about 450 nm to about 495 nm.

The opposite electrode 230 of the first display element to the third display element may be disposed above the display area. As an example, the opposite electrode 230 may include an integral layer to cover the entire display area and be disposed above the display area. That is, the opposite electrode 230 may be integrally formed over the first display element to the third display element and correspond to the first pixel electrode 211 to the third pixel electrode 215. In this case, the opposite electrode 230 may cover the display area and extend to a portion of a non-display area NDA outside the display area DA. As a detailed example, the opposite electrode 230 may be patterned to correspond to each of the first pixel electrode 211 to the third pixel electrode 215.

The opposite electrode 230 may be a light-transmissive electrode or a reflection electrode. In one or more embodiments, the opposite electrode 230 may be a transparent or translucent electrode and may include a metal thin-film having a low work function and including Li, Ca, LiF/Ca, LiF/AI, AI, Ag, or Mg, or a compound thereof. Also, a transparent conductive oxide (TCO) layer including ITO, IZO, ZnO, or In₂O₃ may be further disposed above the metal thin-film.

The organic light-emitting diode may be covered and protected by the encapsulation layer 130. For example, the organic light-emitting diode may be protected from external moisture, oxygen, or the like. The encapsulation layer 130 may include at least one organic encapsulation layer and at least one inorganic encapsulation layer. For example, the encapsulation layer 130 may include a first inorganic encapsulation layer 131, an organic encapsulation layer 133, and a second inorganic encapsulation layer 135.

The first inorganic encapsulation layer 131 may cover the opposite electrode 230 and include silicon oxide, silicon nitride, and/or silicon trioxynitride. Other layers (not shown), such as a capping layer, may be disposed between the first inorganic encapsulation layer 131 and the opposite electrode 230. With the first inorganic encapsulation layer 131 formed along a structure thereunder, an uneven upper surface may be formed. The organic encapsulation layer 133 may be formed to cover the first inorganic encapsulation layer 131 and to form a flat upper surface on the first inorganic encapsulation layer 131. The organic encapsulation layer 133 may include one or more materials selected from polyethylene terephthalate, polyethylene napthalate, polycarbonate, polyimide, polyethylene sulfonate, polyoxymethylene, polyarylate, or HMDSO. The second inorganic encapsulation layer 135 may cover the organic encapsulation layer 133 and include silicon oxide, silicon nitride, silicon trioxynitride, or the like.

Although cracks may be generated in a multilayered structure of the encapsulation layer 130, such cracks may be inhibited or prevented from propagating between the first inorganic encapsulation layer 131 and the organic encapsulation layer 133, or between the organic encapsulation layer 133 and the second inorganic encapsulation layer 135. Thus, the formation of a path, through which external moisture, oxygen, etc. may penetrate the display area may be prevented or reduced.

The quantum dot layers 323 and 333, the light-transmissive layer 313, may be disposed on the adhesive layer 30, and the color filter layers 311, 321, and 331. The upper substrate 400 may be arranged above the color filter layers 311 to 313. The first-color color filter layer 311 to the third-color color filter layer 331 may respectively correspond to the first pixel PX1 to the third pixel PX3. The first-color color filter layer 311 to the third-color color filter layer 331 may be disposed on a first surface of the upper substrate 400. In this case, the term “first surface” refers to a surface (a lower surface) in a direction towards the display unit 10 when the color filter layers 311, 321, and 331 are disposed above the display unit 10. When viewed in a direction (a z-axis direction) perpendicular to an upper surface of the lower substrate 100 or the upper substrate 400 of the display unit 10, the first-color color filter layer 311 to the third-color color filter layer 331 may overlap the first pixel electrode 211 (or the emission layer of the first display element) to the third pixel electrode 215 (or the emission layer of the third display element). Accordingly, the first-color color filter layer 311 to the third-color color filter layer 331 may respectively filter light emitted from the first display element to the third display element.

A first-color filter unit 310 to a third-color filter unit 330 may include the first-color color filter layer 311 to the third-color color filter layer 331. The first-color filter unit 310 to the third-color filter unit 330 may be disposed on the first surface, that is the lower surface, of the upper substrate 400. The light-transmissive layer 313 may be disposed on the first-color color filter layer 311, the second-color quantum dot layer 323 may be disposed on the second-color color filter layer 321, and the third-color quantum dot layer 333 may be disposed on the third-color color filter layer 331.

In detail, the first-color filter unit 310 may include the first-color color filter layer 311 and the light-transmissive layer 313, the second-color filter unit 320 may include the second-color color filter layer 321 and the second-color quantum dot layer 323, and the third-color filter unit 330 may include the third-color color filter layer 331 and the third-color quantum dot layer 333.

The first-color color filter layer 311 may pass light in wavelengths ranging from about 450 nm to about 495 nm, and may block light of other wavelengths. The second-color color filter layer 321 may pass light in wavelengths ranging from about 495 nm to about 570 nm, and may block light of other wavelengths. The third-color color filter layer 331 may pass light in wavelengths ranging from about 630 nm to about 780 nm and may block light of other wavelengths. The first-color color filter layer 311 to the third-color color filter layer 331 may reduce an external reflection of the display device DV.

For example, when external light reaches the first-color color filter layer 311, the light in the wavelengths ranging from about 450 nm to about 495 nm may pass the first-color color filter layer 311, and light in other wavelengths may be absorbed into the first-color color filter layer 311. Therefore, the light in the wavelengths ranging from about 450 nm to about 495 nm among the external light incident to the display device DV may pass the first-color color filter layer 311, and a portion of the light may be reflected from the opposite electrode 230 or the first pixel electrode 211 of the first display element thereunder and may be discharged to the outside. The portion of the external light, which is incident to a location of the first pixel PX1, may be reflected to the outside, external light reflection may decrease. Similar treat of the external light may also be applied to the second-color color filter layer 321 and the third-color color filter layer 331.

The second-color quantum dot layer 323 may convert light having a first wavelength band and generated in the intermediate layer 220 of the second display element into light having a second wavelength band. For example, when light in a wavelength ranging from about 450 nm to about 495 nm is generated in the intermediate layer 220 of the second display element, the second-color quantum dot layer 323 may convert the generated light into light in a wavelength ranging from about 495 nm to about 570 nm. Accordingly, the light in the wavelength ranging from about 495 nm to about 570 nm may be emitted to the outside from the second pixel PX2.

The third-color quantum dot layer 333 may convert light having the first wavelength band and generated in the intermediate layer 220 of the third display element into light having a third wavelength band. For example, when light in a wavelength ranging from about 450 nm to about 495 nm is generated in the intermediate layer 220 of the third display element, the third-color quantum dot layer 333 may convert the generated light into light in a wavelength ranging from about 630 nm to about 780 nm. Accordingly, the light in the wavelength ranging from about 630 nm to about 780 nm may be emitted to the outside from the third pixel PX3.

The second-color quantum dot layer 323 and the third-color quantum-color quantum dot layer 333 may each have a configuration in which quantum dots are distributed in resin.

The quantum dot may have a size of about several nanometers, and the wavelength of light emitted by the quantum dot may depend on the particle size of the quantum dot. That is, the quantum dot may emit light of a certain color according to the particle size, and thus, the quantum dots may have various emission colors, such as blue, red, and green. The particle size of the quantum dot may have a full width of half maximum (FWHM) of the emission wavelength spectrum of about 45 nm or less, preferably about 40 nm or less, and more preferably about 30 nm or less, and the color purity and color reproducibility may be improved within these range. Also, light emitted from the quantum dot may be discharged in all directions, and thus, the viewing angle of the light may be improved. Also, a shape of the quantum dot is not specifically limited, and in more detail, the shape of the quantum dot may be a circle, a pyramid, a multi-armed shape, a cubic nanoparticle, a nanotube, a nanowire, a nanofiber, a plate-shaped nanoparticle, or the like. In addition, the quantum dot may include a semiconductor material, such as cadmium sulfide (Cds), cadmium telluride (CdTe), zinc sulfide (ZnS), or indium phosphide (InP).

Resin included in the second-color quantum dot layer 323 and the third-color quantum dot layer 333 may be transparent. Resin included in the second-color quantum dot layer 323 and the third-color quantum dot layer 333 may be of various types. For example, a polymer resin, such as silicon resin, epoxy resin, acryl, BCB, or HMDSO, may be used as a material for forming the second-color quantum dot layer 323 and the third-color quantum dot layer 333.

The first-color filter unit 310 may not include a quantum dot layer. The first-color filter unit 310 may include the light-transmissive layer 313. For example, the first display element to the third display element may be disposed between the opposite electrode and the first pixel electrode 211 to the third pixel electrode 215 and include the intermediate layer 220 including the first-color emission layer for emitting light in the wavelength included in the first wavelength band. In this case, the light in the wavelength included in the first wavelength band generated in the intermediate layer 220 may be emitted from the first pixel PX1 to the outside without using a quantum dot layer to convert the wavelength of the light. As a quantum dot layer may not be included in the first pixel PX1, the first-color filter unit 310 may not include the quantum dot layer, and may include the light-transmissive layer 313 including transmissive resin.

The light-transmissive layer 313 may include scattering particles. The scattering particles may reduce a luminance ratio between a front and sides of light emitted from a pixel. The light generated from the pixel electrode may pass through the filter unit and may be emitted from each pixel to the outside, and in the case of relatively high luminance at the front and relatively low luminance at the sides, the light may have the luminance ratio between the front and the sides of light emitted from the pixel. At high luminance ratios, performance degradation, such as, a reduced viewing angle or shifted color coordinates, may occur. In the display device DV according to an embodiment, the light-transmissive layer 313 may include scattering particles, light passing through the light-transmissive layer 313 may be scattered by the scattering particles, and thus, the luminance ratio between the front and the sides may be reduced.

The adhesive layer 30 may be disposed on the quantum dot layers 323 and 333 and the light-transmissive layer 313. The adhesive layer 30 may be disposed between the color filter layers 311, 321, and 331, and the quantum dot layers 323 and 333 and the light-transmissive layer 313. The adhesive layer 30 may be, for example, an optical clear adhesive (OCA), but embodiments are not limited thereto. Also, the adhesive layer 30 may include a filler (not shown). The filler may be disposed on the display unit 10 or on the quantum dot layers 323 and 333 and the light-transmissive layer 313. For example, the filler may be disposed between the display unit 10, and the quantum dot layers 323 and 333 and the light-transmissive layer 313. In another example, the filler may be disposed between the quantum dot layers 323 and 333 and the light-transmissive layer 313 and the color filter layers 311, 321, and 331. The filler may buffer external impacts, and the like. The filler may include an organic material, such as methyl silicone, phenyl silicone, or polyimide, urethane-based resin that is an organic sealant, epoxy-based resin, acryl-based resin, or silicone that is an inorganic sealant, but embodiments are not limited thereto. According to embodiment, the adhesive layer 30 may be omitted.

Partitions 600 may be disposed between the first-color color filter layer 311, the second-color color filter layer 321, and the third-color color filter layer 331. For example, partitions 600 may be disposed on sides or around each of the first-color color filter layer 311, the second-color color filter layer 321, and the third-color color filter layer 331. The partitions 600 may define a first-color area to a third-color area in spaces between the adjacent partitions 600, and the first-color area to the third-color area correspond to the first pixel PX1 to the third pixel PX3, respectively.

The partitions 600 may be patterned. The pattern of the partitions 600 may correspond to a non-display portion of the display unit 10 in the display area DA. The pattern of the partitions 600 may correspond to the quantum dot layers 323 and 333, the light-transmissive layer 313. The pattern of the partitions 600 and the color filter layers 311, 321, and 331 may be bonded and may function as a light-shielding layer. In other words, the light may be emitted to the outside through the first-color area to the third-color area, which may correspond to areas where no partitions 600 are located.

The partitions 600 may include a material (e.g., photoresist) that undergo a chemical change when exposed to light. For example, the partitions 600 may include an aromatic bis-azide, methacrylic acid ester, cinnamic acid ester, or the like as a negative photoresist and may include PMMA, naphthoquinone diazide, polybutene-1-sulfone, or the like as a positive photoresist, but the materials are not limited thereto. In an embodiment, the partitions 600 may include a black matrix, a black pigment, a metal material, or the like. The partitions 600 may function as the light-shielding layers, and may include reflective materials, such as Al or Ag, which may increase light efficiency.

The first-color color filter layer 311 to the third-color color filter layer 331 may be formed between the partitions 600 and may correspond to the first pixel PX1 to the third pixel PX3, respectively. The color filter layers 311, 321, and 331 may be formed through, for example, an inkjet process, but embodiments are not limited thereto.

In an embodiment, a bank layer 500 may be disposed between the light-transmissive layer 313, the second-color quantum dot layer 323, and the third-color quantum dot layer 333. In other words, the light-transmissive layer 313, the second-color quantum dot layer 323, and the third-color quantum dot layer 333 may be disposed in the bank layer 500.

The bank layer 500 may include a reflection layer 501 and a central portion 502. The reflection layer 501 may form an upper surface and a side surface of the bank layer 500. The reflection layer 501 may include Ag. The bank layer 500 may reflect light emitted from each of the light-transmissive layer 313, the second-color quantum dot layer 323, and the third-color quantum dot layer 333 in a lateral direction, and may increase the light efficiency of the display device DV. Also, the bank layer 500 may prevent or inhibit the light, which is emitted from the light-transmissive layer 313, from being irradiated towards the second-color quantum dot layer 323 and the third-color quantum dot layer 333. Similarly, the light emitted from the second-color quantum dot layer 323 and the third-color quantum dot layer 333 may be prevented or inhibited from being irradiated onto each other.

The bank layer 500 may be disposed on the encapsulation layer 130. That is, a lower surface of the bank layer 500 may be disposed on the encapsulation layer 130. The bank layer 500 may have an upper surface that has a height higher than an upper surface of the light-transmissive layer 313, the second-color quantum dot layer 323, and the third-color quantum dot layer 333. The upper surface of the bank layer 500 may be generally planar. Side surfaces of the bank layer 500 may be generally convex between the upper surface and the lower surface of the bank layer 500. That is, adjacent portions of the bank layer 500 may have side surfaces that extend toward each other at middle portions thereof.

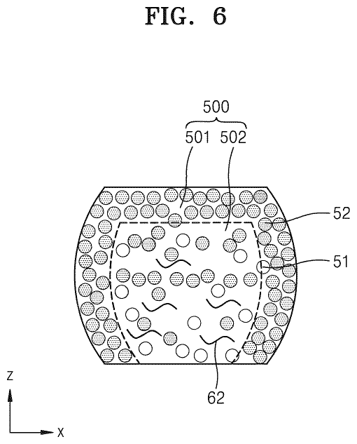

FIG. 6 is an enlarged cross-sectional view showing a bank layer, according to an embodiment. In detail, FIG. 6 schematically shows the bank layer of FIG. 5, according to an embodiment.

The reflection layer 501 disposed adjacent to the upper surface and the side surface of the bank layer 500, and the central portion 502 arranged at a center portion of the bank layer 500. The reflection layer 501 may include a silver (Ag) material 52. In detail, the reflection layer 501 may include Ag colloidal nanoparticles. The central portion 502 of the bank layer 500 may include silver ions (Ag+) 51. Also, the bank layer 500 may include a polymer 62, such as an epoxy-based polymer and an acryl-based polymer.

The reflectivity of the reflection layer 501 included in the bank layer 500 for visible light may be about 70% or higher. The light emitted from each of the light-transmissive layer 313, the second-color quantum dot layer 323, and the third-color quantum dot layer 333 in the lateral direction may be reflected from the reflection layer 501, and the light extraction efficiency may be increased.

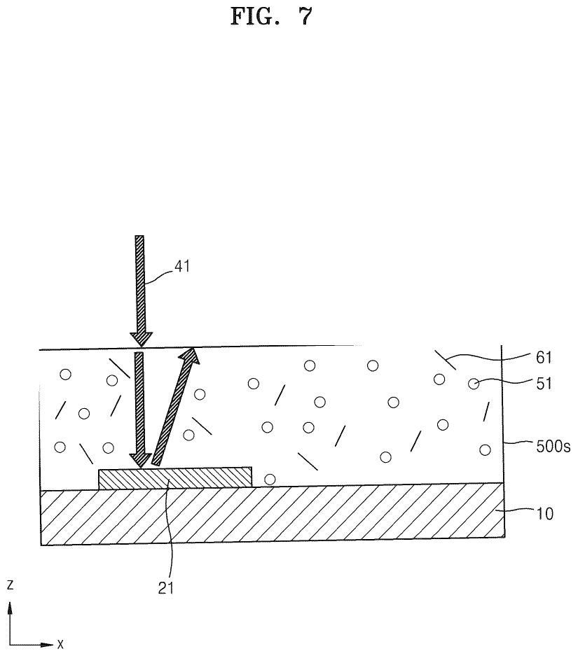

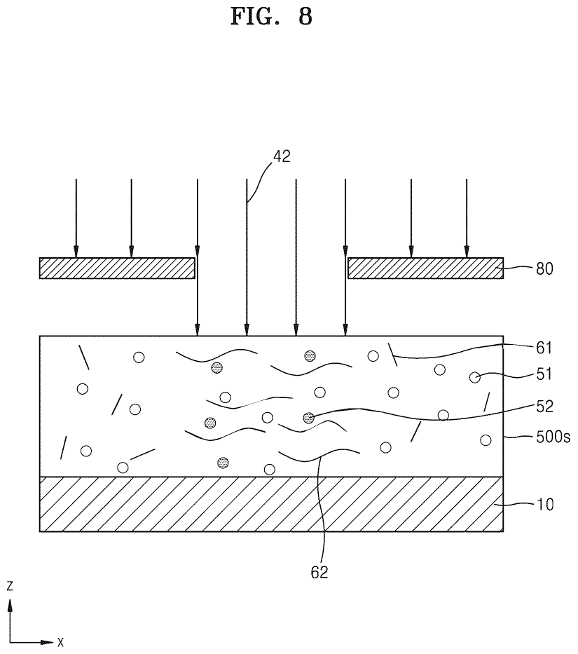

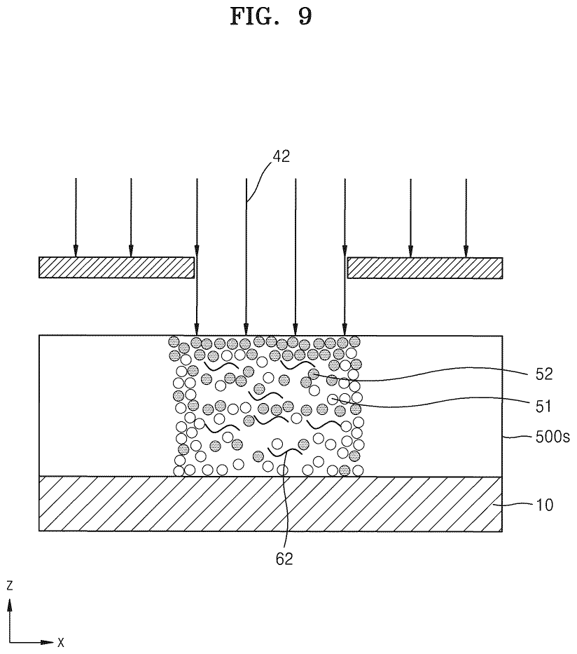

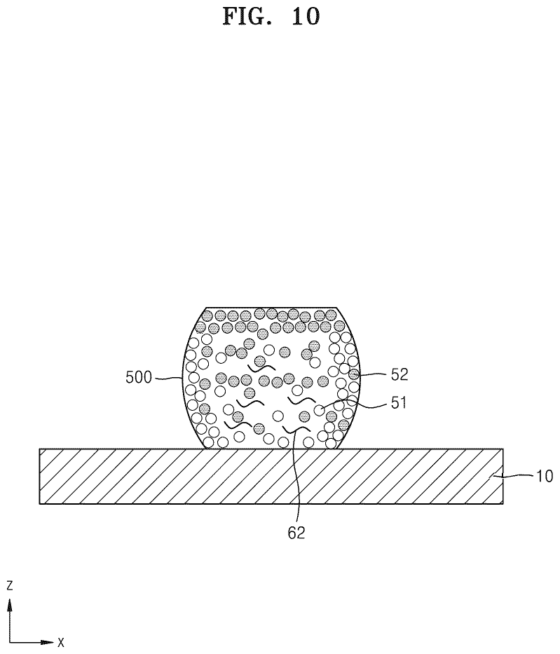

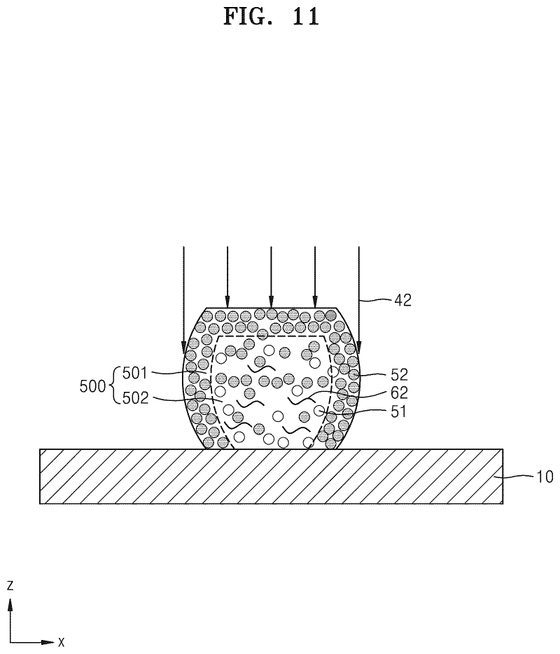

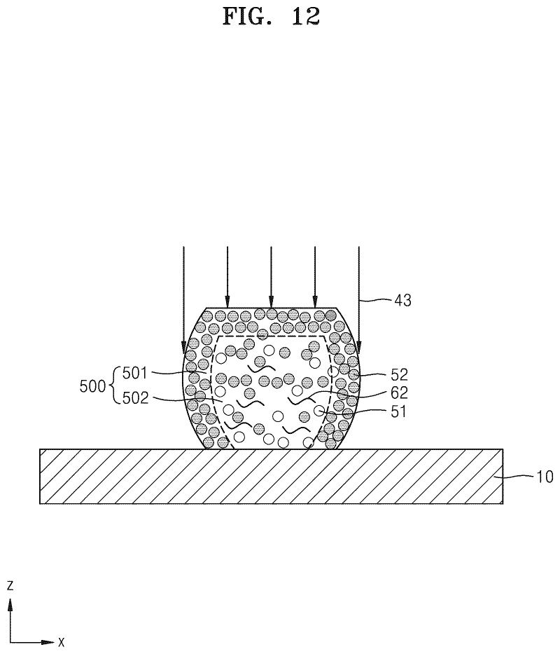

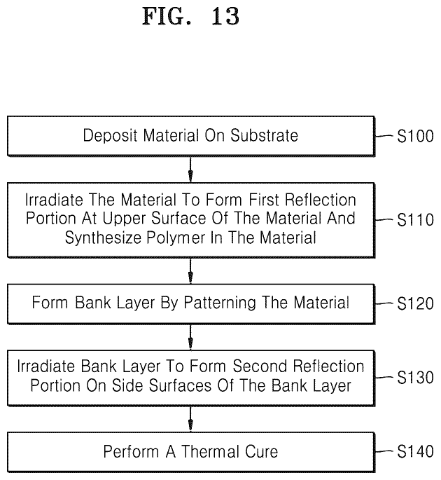

FIG. 7, FIG. 8, FIG. 9, FIG. 10, FIG. 11, and FIG. 12 are schematic cross-sectional views of a method of manufacturing a bank layer. FIG. 13 is a flow diagram of a method of manufacturing a bank layer.

Referring to FIG. 7 and FIG. 13, a material precursor 500s of a bank layer may be disposed on a substrate at S100. For example, the material precursor 500s may be disposed on the display unit 10. The material precursor 500s may be transparent. Infrared rays 41 may be irradiated onto the material precursor 500s and an align key 21 may be used for aligning a mask. The transmittance of the material precursor 500s to the infrared rays 41 may be at least about 14%. As the material precursor 500s may be transparent and the transmittance to the infrared rays 41 may be at least about 14%, when the infrared rays 41 are irradiated onto the material precursor 500s, the infrared rays 41 may reach the align key 21 disposed under the material precursor 500s and the infrared rays 41 may be reflected, and through the reflected infrared rays 41, a photomask (80, see FIG. 8) may be aligned to a location where the bank layer (500, see FIG. 6) is to be formed. When the material precursor 500s is not transparent and the transmittance to the infrared rays 41 may be less than about 14%, the infrared rays 41 irradiated onto the material precursor 500s may fail to reach the align key 21, and the photomask 80 may not be aligned to the location where the bank layer 500 is to be formed, and the stack structure of the display device DV may be misaligned, thereby causing a defect in the display device DV.

The material precursor 500s may include Ag+51. In detail, the material precursor 500s may include silver nitrate (AgNO₃) as a photochemical metal precursor. According to an embodiment, the material precursor 500s may include an acryl-based or epoxy-based monomer 61. When exposed to the ultraviolet rays (42, see FIG. 8), the Ag+51 included in the material precursor 500s may be reduced to Ag 52, and atoms of Ag 52 may form Ag colloidal nanoparticles. In addition, the acryl-based or epoxy-based monomer 61 may be synthesized into a polymer (62, see FIG. 6).

In an embodiment, the material precursor 500s may include a photosensitizer, such as benzophenone-based derivatives or 2,4,6-Trimethylbenzoyl) phosphine oxide, for photoinduced or photocatalytic reduction. According to an embodiment, the material precursor 500s may include a solvent, such as propylene glycol monomethyl ether acetate (PGMEA) or a radical photoinitiator, such as Irgacure, to initiate polymerization.

Referring to FIG. 8, FIG. 9, and FIG. 13, the photomask 80 may be arranged on at least a portion of the material precursor 500s. Through the infrared rays 40 irradiated onto the material precursor 500s and reflected from the align key (21, see FIG. 7) arranged under the material precursor 500s by irradiating the infrared rays 41 onto the material precursor 500s, the photomask 80 may be aligned to the location where the bank layer (500, see FIG. 6) is to be formed.

After the photomask 80 is aligned, the ultraviolet rays 42 may be irradiated onto the photomask 80 and the material precursor 500s S110. The ultraviolet rays 42 may be irradiated onto the material precursor 500s exposed by the photomask 80. The ultraviolet rays 42 may not be irradiated onto the material precursor 500s on which the photomask 80 is arranged.

When the ultraviolet rays 42 are irradiated onto at least a portion of the material precursor 500s, free radicals may be generated from a photosensitive material capable of providing free electrons to the Ag+. Thus, Ag+51 included in the material precursor 500s, onto which the ultraviolet rays 42 are irradiated, may be reduced to Ag 52. Atoms of the Ag 52 may aggregate and form the Ag colloidal nanoparticles. In detail, the upper surface of the material precursor 500s may be irradiated with more ultraviolet rays 42 than an inner portion thereof, more Ag colloidal nanoparticles may be located in a portion of the material precursor 500s adjacent to the upper surface of the material precursor 500s compared to the inner portion thereof, and a first reflection portion may be formed at the upper surface of the material precursor 500s. Also, the epoxy-based or acryl-based monomers 61 included in the material precursor 500s may be synthesized into the polymer 62, wherein the material precursor 500s is irradiated with the ultraviolet rays 42. In detail, free radicals from the radical photoinitiator, such as Irgacure, may initiate the synthesis of the acryl-based or epoxy-based polymer 62.

In the process of irradiating the ultraviolet rays 42 onto at least a portion of the material precursor 500s, the intensity of the ultraviolet rays 42 may be in a range from about 10 mJ to about 1,500 mJ. When the intensity of the ultraviolet rays 42 is less than about 10 mJ, the intensity may not be sufficient enough to initiate the reduction of Ag+ 51 of the material precursor 500s to Ag 52 or the synthesis of the epoxy-based or acryl-based polymer 62, and accordingly, the reduction and the synthesis of the polymer 62 may not occur. When the intensity of the ultraviolet rays 42 is greater than about 1,500 mJ, the ultraviolet rays 42 may be irradiated onto portions other than the portion where the bank layer (500, see FIG. 6) is to be formed. When the ultraviolet rays 42 are irradiated onto portions with the photomask 80 other than the portion where the bank layer 500 is to be formed, it may be challenging to control a size of the bank layer 500, and the size of the bank layer 500 may exceed a certain level, resulting in defects in the display device DV.

Referring to FIG. 10 and FIG. 13, the portion of the material precursor 500s where the photomask (80, see FIG. 8) is arranged and the ultraviolet rays 42 are not irradiated may be removed. As at least a portion of the material precursor 500s onto which the ultraviolet rays 42 are not irradiated may be removed, the bank layer 500 may be formed S120. In detail, at least a portion of the material precursor 500s onto which the ultraviolet rays 42 are not irradiated may be removed using a developer. That is, the material precursor 500s may be patterned to form the bank layer 500.

Referring to FIG. 11 and FIG. 13, after the remaining portion of the material precursor 500s has been removed and the bank layer 500 is formed, the ultraviolet rays 42 may be secondarily irradiated onto the bank layer 500 S130. In the process of secondarily irradiating the ultraviolet rays 42 onto the bank layer 500, the ultraviolet rays 42 may be irradiated onto the upper surface of the bank layer 500 and the side surfaces of the bank layer 500. As the ultraviolet rays 42 are irradiated onto the side surfaces of the bank layer 500, Ag colloidal nanoparticles, in which the atoms of Ag 52 aggregate, may be formed on the side surface of the bank layer 500. As the Ag colloidal nanoparticles may be formed on the upper surface and the side surfaces of the bank layer 500, and a second reflection portion may be formed at the side surfaces of the bank layer 500. The reflection layer 501 may include the first reflection portion formed at the upper surface of the bank layer 500 and the second reflection portion formed at the side surfaces of the bank layer 500.

The bank layer 500 may include the reflection layer 501 that is disposed at the upper surface and the side surfaces of the bank layer 500 and includes Ag 52. The reflectivity for the reflection layer 501 to visible rays may be about 70% or higher. The reflectivity of the reflection layer 501 of the bank layer 500 for visible rays may be about 70% or higher and the light emitted from each of the light-transmissive layer 313, the second-color quantum dot layer 323, and the third-color quantum dot layer 333 in the lateral direction may be reflected from the reflection layer 501. According to an embodiment, the bank layer 500 may include the reflection layer 501 and the light extraction efficiency of the display device DV may be improved.

Referring to FIG. 12 and FIG. 13, after the process of secondarily irradiating the ultraviolet rays 42, a process of thermally curing the bank layer 500 may be additionally or selectively performed S140. In the process of thermally curing the bank layer 500, heat 43 may be applied to the bank layer 500, and the bank layer 500 may be cured. In detail, at least a portion of the epoxy-based or acryl-based monomers (61, see FIG. 7) remaining in the bank layer 500 may be synthesized into the polymer (62, see FIG. 6).

To improve the light extraction efficiency of the display device, the display device may include the reflection layer on the side surface and the lower surface of the bank layer. While the reflection layer on the side surface and the lower surface of the bank layer may be formed using a process of stacking the reflection layer, the process may be complicated and time-consuming, and thus, the efficiency of the process of forming the display device may be reduced.

In an embodiment, the irradiation of the ultraviolet rays 42 onto the material precursor 500s for forming a bank layer may simultaneously allow the reduction of Ag+51 in the material precursor 500s for forming a bank layer to Ag 52 and the formation of Ag colloidal nanoparticles from the atoms of Ag 52 on the upper surface of the material precursor 500s irradiated with the ultraviolet rays 42, as well as the synthesis of acryl-based or epoxy-based monomers 61 into the polymer 62. After the bank layer 500 is formed by removing at least a portion of the material precursor 500s, the ultraviolet rays 42 may be secondarily irradiated onto the bank layer 500 to form the Ag colloidal nanoparticles on the side surfaces of the bank layer 500, which enables the formation of the reflection layer 501 in the bank layer 500 that is adjacent to the upper and side surfaces of the bank layer 500. The bank layer 500 may include the reflection layer 501. Through a process of irradiating the ultraviolet rays 42, the reflection layer 501 may be formed in the bank layer 500 adjacent to the upper and side surfaces of the bank layer 500. The reflection layer 501 may contribute to improving light extraction efficiency in the display device DV and achieving time savings and process simplification in the manufacturing of the display device DV at the same time, thereby increasing the efficiency in the manufacturing processes of the display device.

According to the one or more embodiments, a display device with improved efficiency and reliability and a method of manufacturing the display device may be realized. However, the scope of the disclosure is not limited by the effects.

It should be understood that embodiments described herein should be considered in a descriptive sense and not for purposes of limitation. Descriptions of features or aspects should be considered as available for other similar features or aspects. While embodiments have been described with reference to the figures, it will be understood by those of ordinary skill in the art that various changes in form and details may be made therein without departing from the spirit and scope as defined by the following claims.

What is claimed is:

1. A method of manufacturing a display device, the method comprising:
disposing a material precursor of a bank layer on a substrate;
irradiating first ultraviolet rays onto at least a portion of the material precursor to form a first reflection portion; and
removing at least a portion of the material precursor to form the bank layer.

2. The method of claim 1, further comprising:
disposing a photomask onto the material precursor before the irradiating the first ultraviolet rays onto the portion of the material precursor,
wherein the portion of the material precursor removed includes a portion of the material not irradiated by the first ultraviolet rays.

3. The method of claim 1, wherein the material precursor comprises silver ions (Ag+) and the irradiating of the first ultraviolet rays onto the portion of the material precursor comprises reducing the Ag+ to silver (Ag).

4. The method of claim 1, wherein the material precursor comprises an acryl-based monomer or an epoxy-based monomer,
wherein the irradiating of the first ultraviolet rays onto the portion of the material precursor comprises synthesizing the acryl-based monomer or the epoxy-based monomer into a polymer.

5. The method of claim 1, wherein the material comprises at least one of a photoinitiator or a photosensitizer.

6. The method of claim 1, wherein the material precursor comprises silver nitrate (AgNO₃) and the irradiating of the first ultraviolet rays onto the portion of the material precursor comprises reducing silver ions (Ag+) of a AgNO₃ to silver (Ag).

7. The method of claim 1, further comprising aligning a photomask to the material precursor using infrared rays, wherein a transmittance of the material precursor to the infrared rays is about 14% or higher.

8. The method of claim 1, wherein in the irradiating of the first ultraviolet rays onto the portion of the material precursor, an intensity of the first ultraviolet rays is in a range from about 10 mJ to about 1,500 mJ.

9. The method of claim 3, wherein the irradiating of the first ultraviolet rays onto the portion of the material precursor comprises generating free radicals from a photosensitive material to provide free electrons to the Ag+ of the material precursor.

10. The method of claim 3, wherein, in the irradiating of the first ultraviolet rays onto the portion of the material, Ag atoms aggregate to form Ag colloidal nanoparticles.

11. The method of claim 1, further comprising, after the forming of the bank layer, irradiating second ultraviolet rays onto the bank layer to form a second reflection portion at a side surface of the bank layer.

12. The method of claim 11, further comprising, after the irradiating of the second ultraviolet rays onto the bank layer, curing the bank layer by applying heat to the bank layer.

13. The method of claim 11, wherein a reflection layer is formed of the first reflection portion disposed at an upper surface of the bank layer and the second reflection portion disposed at the side surface of the bank layer, and the reflection layer comprises Ag.

14. The method of claim 13, wherein a transmittance of the reflection layer of the bank layer to visible light is about 70% or higher.

15. A method of manufacturing a display device, the method comprising:
disposing a material precursor of a bank layer on an encapsulation layer;
irradiating first ultraviolet rays onto at least a portion of the material precursor to form a first reflection portion at an upper surface of the material precursor;
removing, after forming the first reflection portion, at least a portion of the material precursor disposed above a pixel electrode to form a bank layer; and
irradiating second ultraviolet rays onto the bank layer to form a second reflection portion at a side surface of the bank layer.

16. The method of claim 15, further comprising, after the irradiating of the second ultraviolet rays onto the bank layer, curing the bank layer by applying heat.

17. The method of claim 15, wherein the material precursor comprises silver ions (Ag+), and an acryl-based monomer or an epoxy-based monomer,
wherein the irradiating of the first ultraviolet rays onto the portion of the material precursor comprises simultaneously synthesizing the acryl-based monomer or the epoxy-based monomer into a polymer and reducing the silver ions (Ag+) to silver (Ag).

18. A display device comprising:
a substrate;
a bank layer disposed above the substrate and comprising a reflection layer formed of silver (Ag) at an upper surface and a side surface of the bank layer, and a central portion comprising Ag ions (Ag+); and
a light-transmissive layer, a first-color quantum dot layer, and a second-color quantum dot layer disposed in openings of the bank layer.

19. The display device of claim 18, wherein the bank layer comprises an epoxy-based polymer or an acryl-based polymer.

20. The display device of claim 18, wherein transmittance of the reflection layer of the bank layer to visible light is about 70% or higher.
